(19) United States
(12) Patent Application Publication
(10) Pub. No.: US 2008/0231303 A1
(43) Pub. Date: Sep. 25, 2008

(54) SEMICONDUCTOR DEVICE FOR ELECTRICAL CONTACTING SEMICONDUCTOR DEVICES

(75) Inventors: Jochen Kallscheuer, Munchen (DE); Sascha Nerger, Munchen (DE); Bernhard Ruf, Sauerlach (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 12/052,070

(22) Filed: Mar. 20, 2008

(30) Foreign Application Priority Data
Mar. 20, 2007 (DE) 10 2007 013 338.5

(51) Int. Cl. G01R 31/26; H01L 23/482; G01R 1/067

(52) U.S. Cl. 324/760; 257/750; 257/E23.017

(57) ABSTRACT

A semiconductor device with a number of contact pads for the electrical contacting of the semiconductor device is disclosed. A padding layer, which is manufactured of a hard material, is provided at least partially below an upper layer of the contact pads.

### CROSS-REFERENCE TO RELATED APPLICATIONS

This Utility Patent Application claims priority to German Patent Application No. DE 10 2007 013 338.5, filed on Mar. 20, 2007, which is incorporated herein by reference.

### BACKGROUND

The following statements relate to the technical field of semiconductor devices, with reference being made to a device and a method for electrical contacting for the testing of semiconductor devices.

The term semiconductor devices means in general integrated circuits or chips, respectively, as well as single semiconductors such as, for instance, analog or digital circuits or single semiconductors, as well as semiconductor memory devices such as, for instance, functional memory devices (PLAs, PALs etc.), and table memory devices (ROMs or RAMs, SRAMs or DRAMs).

For the common manufacturing of a plurality of semiconductor devices such as, for instance, integrated circuits, thin discs of monocrystalline silicon are used, which are referred to as wafers in technical language. In the course of the manufacturing process, the wafers are subject to a plurality of coating, exposure, etching, diffusion, and implantation process steps, etc. so as to implement the circuits of the devices on the wafer. Subsequently, the devices implemented on the wafer may be separated from each other, for instance, by sawing, scratching, or breaking. After processing has been finished, the semiconductor devices are individualized in that the wafer is sawn apart, or scratched and broken, so that the individual semiconductor devices are then available for further processing.

After performing the above-mentioned wafer processing, the devices implemented on the wafer may, for instance, be tested in so-called wafer tests by means of appropriate test devices. After the sawing apart or the scratching and breaking, respectively, of the wafer, the chips that are then available individually are molded in a plastics mass, wherein the semiconductor devices obtain specific packages such as, for instance, so-called TSOP or FBGA packages, etc. The devices are equipped with contact faces in the form of so-called contact pads by which the circuits of the semiconductor device can be contacted electrically. During the molding of the chips in the plastics mass, these contact faces or contact pads are connected with external connection pins or contact balls via so-called bonding wires (bonding).

As mentioned above, semiconductor devices are, for examining their functions, usually subject to comprehensive tests for examining the functions in the course of the manufacturing process in the semi-finished and/or finished state even prior to being molded or incorporated in corresponding semiconductor modules. By using appropriate test systems or so-called test cells, it is also possible to perform test methods on waver level even prior to the individualization of the semiconductor devices so as to be able to examine the operability of the individual semiconductor devices still on the wafer prior to their further processing.

One aspect serves, for example, to be use during the testing of the operability of semiconductor devices with appropriate test systems or test devices. In order to electrically connect the semiconductor device to be tested in a test station with the test system, a specific contacting device, namely a semiconductor device test card or a so-called probe card is usually used. Needle-shaped contact tips or contact needles are provided at the probe card which contact the corresponding contact faces or contact pads of the semiconductor devices to be tested.

By means of the probe card it is possible to generate the signals required for the testing of semiconductor devices that are available on the wafer by means of the test device connected with the probe card, and to introduce them into the respective contact pads of the semiconductor devices by means of the contact needles provided at the probe card. The signals output by the semiconductor device at corresponding contact pads in reaction to the input test signals are in turn tapped by the needle-shaped connections of the probe card and, for instance, transferred to the test device via a signal line connecting the probe card with the test device, where an evaluation of the corresponding signals may take place.

During the testing on wafer level, the chip-internal voltages are, for instance, impressed from outside via current supply channels by the probe card of a test system and further via supply voltage contact points on the chip. Via the contact needles of the probe card, the output voltage and signals generated by the semiconductor device are also tapped at the corresponding contact pads of the semiconductor device and transmitted to the test system or the tester, respectively, so as to examine the operability of the semiconductor device.

When contacting the contact faces of the semiconductor devices, they may be damaged by the sharp contact needles. For example, a repeated deep penetration of a contact needle tip of the probe card in the contact pads may cause problems during the above-described bonding in which the contact pads are connected with the external connection pins. This may result in increased contact failures and thus in a higher failure rate (yield loss). One reason for these problems during bonding are scratches produced by the contact needles, and the depth of the needle impressions left by the contact needles in the contact pad after contacting.

During a test process, the contact pads of memory chips are partially contacted up to six times. On every contacting, the tip of the contact needle penetrates into the contact pad, for instance, up to 400 μm. By the varying of the contact position on the contact pad, up to six individual needle impressions (“scratches”) are then available on the contact pad. If the chip is bonded later, these damages of the contact pads may cause contact failures, which results in the discarding of the chip. In order to counter-act, one has, for instance, been trying to reduce the number of needle impressions or scratches, which is usually related with higher costs for the contacting device, for example, the probe card.

For these and other reasons, there exists a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a schematic representation of a perspective view on a contact pad of a semiconductor device.

FIGS. 2A and 2B each a schematic representation of a cross-section through the contact pad of a semiconductor device in different states.

FIGS. 3A and 3B each a schematic representation of a cross-section through the contact pad of a semiconductor device in different states according to an embodiment.

FIGS. 4A and 4B each a perspective representation of a part of a contacting device in different states in accordance with an embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One aspect consists in providing a semiconductor device with novel contact pads for the electrical contacting of the semiconductor device which reduces the above-mentioned problems. Another aspect consists in providing a device and a method for the electrical contacting of semiconductor devices for performing test methods which reduce the above-mentioned problems.

In accordance with one embodiment, the above-mentioned embodiments are solved by a contact pad that restricts the depth of penetration of the contact needle in the contact pad. This is achieved in that an upper layer of the contact pad is at least partially padded by a padding layer that is manufactured of a hard material. The padding layer may, for instance, be manufactured of a material that is harder than the molding material in which the semiconductor device is molded. The padding layer may also be manufactured of a material that is harder than the material of which the contact pads are manufactured.

Due to the padding of the upper layer of the contact pad with a padding layer of a hard material, a contact needle that contacts the contact pad cannot penetrate any further into the contact pad than to the hard padding layer. Due to the hardness of the padding layer, it is no longer possible for the contact needle to penetrate deeply into the padding layer. Thus, the depth of penetration of the contact needle into the contact pad is restricted by the hard padding layer.

The contact pads may at least partially have a multi-layer structure and thus be constructed as a multi-layer contact pad. At least one layer below the surface of the contact pads includes a hard material. Below each contact pad, a respective separate padding layer may be provided. Alternatively, a number of contact pads may be padded by a joint padding layer.

On contacting a multi-layer contact pad, the needle tip first of all penetrates an oxidation layer on the contact pad and penetrates into the material of the upper layer, so that a reliable electrical contact between the contact needle and the contact pad is established. A deeper penetration of the contact needle through the upper layer of the contact pad beyond the bottom limit of the upper layer is finally prevented by the harder padding layer. Accordingly, the depth of penetration of the contact needle is determined by the thickness of the upper layer of the contact pad along with the limiting face to the padding layer.

By the padding layer it is possible to prevent damages to active elements of the semiconductor device which are positioned below the contact pad and may be caused by the contacting of the contact pad by means of the contact needles. Thus, a lower failure rate in the production may be achieved. The “contact yield” during bonding may be increased, and the scratches in the contact pads may be restricted to a smaller depth.

The upper layer of the multi-layer contact pad may, for instance, be manufactured of aluminum, copper, and/or another material having a good electrical conductivity. The padding layer may, for instance, be manufactured of tungsten which is relatively hard. The padding layer may also be manufactured of a material mixture of hard and/or hardened materials.

The padding layer may substantially have the same lateral dimensions as the upper layer of the contact pad. Alternatively, the padding layer may project at least partially beyond the lateral dimensions of the upper layer of the contact pad. The contact pad and the padding layer positioned therebelow may be integrated in the semiconductor device. The surface of the contact pad may be on a level with the surface of the semiconductor device. The upper layer of the contact pad may be embedded in the padding layer positioned therebelow.

According to a further aspect, the above-mentioned embodiments are solved by a method for testing semiconductor devices by means of a contacting device comprising a number of contact needles for the electrical contacting of the contact pads of a semiconductor device to be tested, and for the electrical connection of the semiconductor device with a test system, the method comprising:
contacting a number of contact pads of the semiconductor device with the contact needles of the contacting device;
performing one or a plurality of test methods for testing the semiconductor device;
heating a number of contact pads by means of light beams or light pulses.

With this proceeding, the above-mentioned embodiments are solved by an “active repairing” of the contact pads. In so doing, the contact pad is, for example, in the region of the needle impressions, surface-fused by short-term heating of the surface and the upper layer of the contact pad such that the material of the contact surface liquefies and fills needle impressions or deep scratches in the contact pad. This process may be referred to as so-called active “healing” since the surface of the contact pad is freed from scratches and thus planarized and hence “healed” in a certain manner. Such a process is also referred to as “annealing” in technical language.

The intensity of the light beams or light pulses may be chosen such that the upper layer of the contact pads is at least partially molten by the light beams or light pulses. The upper layer of the contact pad may, for instance, be heated for a short time by a laser cutter. In so doing, the contact pad may be surface-fused by the light beams or the light pulses at least in the region of the upper layer of the contact pad at which the contact needle has contacted the contact pad.

By the light beams or light pulses, a temperature may be generated on the surface of the contact pad which lies above the melting temperature of the material of which the upper layer of the contact pad is manufactured. Since the contact pads are, as a rule, manufactured of aluminum or copper, a temperature may be generated by means of the light beams or the light pulses on the surface of the contact pad which lies above the melting temperature of aluminum or copper.

In accordance with yet another aspect, the above-mentioned embodiments are solved by a device that serves for the electrical contacting of a semiconductor device to be tested, and for the electrical connection of the semiconductor device with a test system which includes contact needles for the contacting of contact pads of the semiconductor device to be tested, wherein the device is equipped with a number of optical fibers through which it is possible to direct light beams or light pulses on the contact pads of the semiconductor device to be tested so as to heat a number of contact pads.

To this end, at a number of contact needles of the probe card, at least one optical fiber is attached through which light beams or light pulses are conducted. The optical fiber is oriented such that the light beam or light pulse conducted through the optical fiber hits the surface of a contact pad. The optical fibers may, for example, be oriented such that the light beam or light pulse conducted through the optical fiber is focused on the region of the surface of the contact pad at which the contact needle has contacted the contact pad.

The contacting device in accordance with one embodiment, includes further a light source or a laser light source that generates light pulses or laser light pulses. The laser light source is in one case adapted to be controlled such that the length and/or the intensity of the light pulses or laser light pulses is adjustable. The length and the intensity of the light pulses or laser light pulses is chosen such that they heat the surface and the upper layer of the contact pad to such an extent that they surface-fuse at least partially. The liquefied material on the surface of the contact pad flows into the needle impressions or scratches in the contact pad and is thus capable of filling them and of planarizing the surface of the contact pad.

The optical fiber may be connected with the control of the probe card by means of a logic on the probe card so as to heat the surface of the contact pads damaged by the contact needle by means of a corresponding light or laser pulse, and to smooth it in the above-mentioned manner.

The surface of the contact pads may, for instance, also be heated for a short time only by means of a laser cutter. The positions of the contact pads on the chip may be directly assumed from the design of the corresponding semiconductor device which is also used for the positioning of the contact needles. This means, for the positioning of the contact needles on the contact pads, the positions of the contact pads on the semiconductor device can be used which are known from the layout of the corresponding semiconductor device and are used for the design of the semiconductor device.

At every contact needle, at least one optical fiber may be arranged which may be oriented such that the light beam or light pulse conducted through the optical fiber is focused on the region of the surface of the contact pad at which the contact needle has contacted the corresponding contact pad. A plurality of optical fibers may also be arranged at one contact needle which may each be oriented such that the light beams or light pulses conducted through the optical fibers are focused on the region of the surface of the contact pad at which the contact needle has contacted the corresponding contact pad.

The irradiation of the surface or of the upper layer, respectively, of the contact pads by means of light beams or light pulses conducted through the optical fiber may be performed once the contact needle has been lifted off the contact pad after the contacting. The movement for lifting the contact needle off the contact pad is expediently performed by optical control, by a contact test, or by Z-height determination.

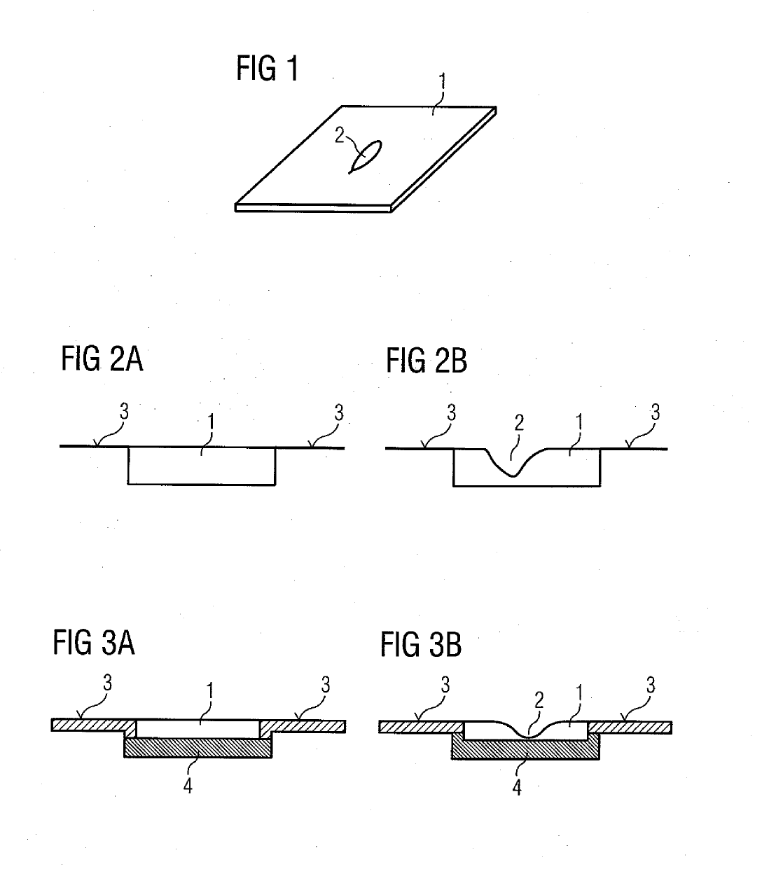

FIG. 1 illustrates a schematic representation of a perspective view on a contact pad of a semiconductor device according to prior art, wherein only the contact pad 1 is illustrated without the semiconductor device. The contact pad 1 illustrated in FIG. 1 has quadrangular dimensions and has thus a rectangular surface. In the region of the middle of the surface, a needle impression or a scratch 2 is illustrated which was caused by the contacting of the contact pad 1 by means of a contact needle (not illustrated).

FIGS. 2A and 2B each illustrate a schematic representation of a cross-section through the contact pad of a semiconductor device according to prior art in different states. The contact pad 1 has a cubic volume and is integrated in the semiconductor device, so that the surface of the contact pad 1 lies substantially on a level with the surface 3 of the semiconductor device. FIG. 2A illustrates the contact pad 1 in the undamaged state with a regular surface before it was contacted by a contact needle.

FIG. 2B illustrates the contact pad 1 in a state after it was contacted by a contact needle. As is illustrated in FIG. 2B, the contact needle has left a needle impression or a scratch 2 in the surface of the contact pad 1 which projects into almost the entire depth of the contact pad 1. Such needle impressions or scratches 2 may cause problems during the bonding of the contact pad 1, which may result in contact failures and in the discarding of the corresponding chip 3.

FIGS. 3A and 3B each illustrate a schematic representation of a cross-section through the contact pad of a semiconductor device in different states according to an embodiment. As is illustrated in FIG. 3A, the contact pad includes an upper layer 1 and a padding layer 4 that is positioned below the upper layer 1 and consists of a hard material. The padding layer 4 may, for instance, be manufactured of a material that is harder than the packing material (molding material) in which the semiconductor device is molded. The padding layer 4 may also be manufactured of a material that is harder than the material of which the contact pads 1 are manufactured.

The contact pad consequently has a multi-layer structure and thus constitutes a multi-layer contact pad. There may also be provided more than the layers illustrated in FIGS. 3A and 3B. Thus, a multi-layer contact pad may, for instance, include a plurality of layers 1 or a plurality of padding layers 4 which may also be arranged in alternate order.

In the embodiment illustrated in FIGS. 3A and 3B, the upper layer 1 of the contact pad and the padding layer 4 positioned therebelow are each integrated in the semiconductor device, wherein the surface of the contact pad 1 is on a level with the surface of the semiconductor device. The dimensions of the padding layer 4 project beyond the lateral dimensions of the upper layer 1 of the contact pad. Furthermore, the upper layer 1 of the contact pad is embedded in the padding layer 4 positioned therebelow.

The padding of the upper layer 1 of the contact pad by a padding layer of a hard material effects that a contact needle that contacts the contact pad cannot penetrate much further into the upper layer 1 of the contact pad than to the hard padding layer 4. By the hardness of the padding layer it is not possible for the contact needle to penetrate deeply into the padding layer 4. Thus, the depth of penetration of a contact needle into the contact pad 1 is restricted by the hard padding layer 4.

FIG. 3B illustrates a schematic cross-section through the contact pad of FIG. 3A in a state after it was contacted by a contact needle (not illustrated). By the contacting, the contact needle left a needle impression or a scratch 2 in the upper layer 1 of the contact pad. During the contacting of the multi-layer contact pad, the needle tip of the contact needle penetrates into the material of the upper layer 1, so that an electrical contact between the contact needle and the contact pad is established. A deeper penetration of the contact needle through the upper layer 1 of the contact pad beyond the lower limit of the upper layer is, however, prevented by the harder padding layer 4. As is illustrated in FIG. 3B, the needle impression or the scratch 2 in the upper layer 1 of the contact pad only projects to the limiting face between the upper layer 1 and the padding layer 4.

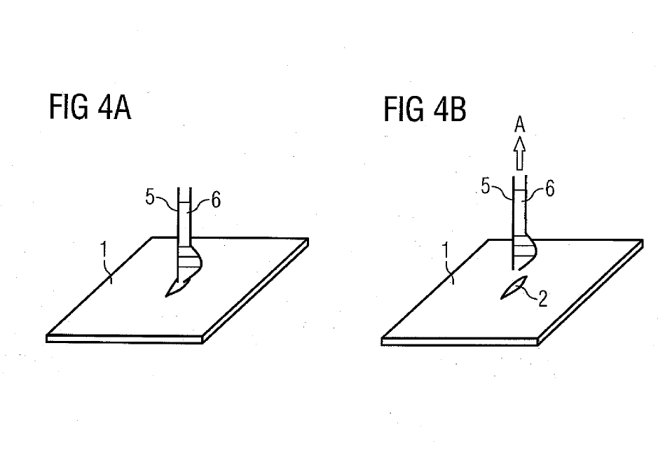

FIGS. 4A and 4B each illustrate a perspective representation of a part of a contacting device in different operating states according to one embodiment. In both FIGS. 4A and 4B, a contact pad 1 is illustrated which has a substantially rectangular surface. In the operating state illustrated in FIG. 4A, the surface 1 of the contact pad is contacted by a contact needle 5 of a contacting device. In FIG. 4A only one contact needle 5 is illustrated, the needle tip of which contacts the surface 1 of the contact pad or penetrates into the upper layer 1 of the contact pad, respectively.

In the operating state illustrated in FIG. 4B, the contact needle 5 of the contacting device has been lifted off the surface 1 of the contact pad in the direction of the arrow A, so that the contact needle 5 no longer contacts the contact pad 1, but is positioned at a distance above it. FIG. 4B illustrates that a needle impression or a scratch 2 has remained below the contact needle 5 in the surface 1 of the contact pad due to the contacting.

The device according to one embodiment is equipped with a number of optical fibers 6 through which it is possible to direct light beams or light pulses onto the contact pad 1 so as to heat the contact pad. To this end, an optical fiber 6 is attached to the contact needle 5 through which it is possible to conduct light beams or light pulses. The free and open end of the optical fiber 6 is positioned and oriented such that the light beam or light pulse conducted through the optical fiber 6 hits the surface 1 of the contact pad. The optical fiber 6 is further oriented such that the light beam or light pulse conducted through the optical fiber is focused on the region on the surface 1 of the contact pad at which the contact needle has contacted the contact pad and at which the needle impression 2 is positioned.

By means of a light source or a laser light source (not illustrated), light pulses or laser light pulses are generated which heat the surface 1 or the upper layer of the contact pad to such an extent that they surface-fuse at least partially. The liquefied material of the upper layer of the contact pad flows on the surface 1 into the needle impressions or scratches 2 in the contact pad and fills same, so that the surface 1 of the contact pad becomes planarized again. The surface 1 of the contact pad may, for instance, also be heated for a short time only by means of a laser cutter, wherein the temperature generated on the surface 1 of the contact pad lies for a short time only above the melting point of the material of which the upper layer 1 of the contact pad is manufactured.

In order to “repair” every contacted contact pad 1 of a tested semiconductor device in this way, at least one optical fiber 6 is arranged at every contact needle 5 which is oriented such that the light beam or light pulse conducted through the optical fiber 6 hits the region on the surface 1 of the contact pad at which the contact needle 5 has contacted the corresponding contact pad. A plurality of optical fibers 6 may also be provided at one contact needle 5, which are each oriented such that the light beams or light pulses conducted through the optical fibers 6 are directed on the region on the surface 1 of the contact pad at which the contact needle has contacted the corresponding contact pad.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising:
a number of contact pads for the electrical contacting of the semiconductor device;
a padding layer, which is manufactured of a hard material, at least partially provided below an upper layer of the contact pads.

2. The semiconductor device of claim 1, wherein the contact pads at least partially have a multi-layer structure, and wherein at least one layer below the surface of the contact pads comprises a hard material.

3. The semiconductor device of any of claims 1, wherein a separate padding layer is provided below every contact pad.

4. The semiconductor device of claim 1, wherein the padding layer has substantially the same lateral dimensions as the upper layer of the contact pad.

5. The semiconductor device of claim 1, wherein the dimensions of the padding layer project at least partially beyond the lateral dimensions of the upper layer of the contact pad.

6. The semiconductor device of claim 1, wherein a number of contact pads is padded by a joint padding layer.

7. The semiconductor device of claim 1, wherein at least one contact pad and the padding layer positioned therebelow are integrated in the semiconductor device.

8. The semiconductor device of any of claim 1, wherein at least the upper layer of the contact pad is embedded in the padding layer.

9. The semiconductor device of any of claim 1, wherein at least the upper layer of the contact pad is manufactured of aluminum and/or copper, and the padding layer is formed of tungsten and/or of a hardened material.

10. A device that serves for the electrical contacting of a semiconductor device to be tested and for the electrical connection of the semiconductor device with a test system, the device comprising:
contact needles for the contacting of contact pads of the semiconductor device to be tested;
a number of optical fibers through which it is possible to direct light beams or light pulses on the contact pads of the semiconductor device to be tested so as to heat a number of contact pads.

11. The device of claim 10, wherein it is possible to direct laser light beams or laser light pulses through the optical fibers on the contact pads of the semiconductor device to be tested so as to heat the contact pads.

12. The device of claim 10, wherein at least one optical fiber is arranged at a contact needle.

13. The device of claim 10, wherein at least one optical fiber is arranged at every contact needle.

14. The device of claim 10, wherein the optical fibers are oriented such that the light beam or light pulse conducted through the optical fiber hits the surface of the contact pads.

15. The device of claim 10, wherein the optical fibers are oriented such that the light beam or light pulse conducted through the optical fiber is focused on the region on the surface of the contact pad at which the contact needle has contacted the contact pad.

16. The device of claim 10, further comprising a light source or a laser light source that generates light pulses or laser light pulses, wherein the light source or the laser light source is adapted to be controlled such that the length and/or the intensity of the light pulses or laser light pulses is adjustable.

17. The device of claim 10, wherein the movement of the optical fibers and of the contact needles is performed by optical control, contact test, or Z-height determination.

18. A method for testing semiconductor devices by means of a contacting device with a number of contact needles for the electrical contacting of the contact pads of a semiconductor device to be tested and for the electrical connection of the semiconductor device with a test system, wherein the method comprises:
contacting a number of contact pads of the semiconductor device with the contact needles of the contacting device;
performing one or a plurality of test methods for testing the semiconductor device; and
heating a number of contact pads using light beams or light pulses.

19. The method of claim 18, wherein the length and/or the intensity of the light beams or light pulses is/are chosen such that an upper layer of the contact pads is at least partially molten by the light beams or light pulses.

20. The method of claim 18, wherein the contact pad is molten by the light beams or light pulses at least in the region in which the contact needle has contacted the contact pad.

21. The method of claim 18, wherein the contact pad is heated for a short time.

22. The method of claim 18, wherein the irradiation of the contact pad by means of light beams or light pulses is performed after the contact needles have been lifted off the contact pads after the contacting.

23. The method of claim 18, wherein, by the light beams or light pulses, a temperature which lies above the melting temperature of the material of which the upper layer of the contact pad is manufactured is generated at least on the surface of the contact pad.

24. The method of claim 18, wherein, for positioning the contact needles on the contact pads, the positions of the contact pads on the semiconductor device are used from the design of the corresponding semiconductor device.

25. A semiconductor device comprising:
contact needles for contacting contact pads of the semiconductor device to be tested;
means for directing light on the contact pads of the semiconductor device to be tested so as to heat a number of contact pads.
